(19) United States
(12) Patent Application Publication
(10) Pub. No.: US 2020/0152567 A1
(43) Pub. Date: May 14, 2020

(54) SYSTEM AND METHOD OF LAYING OUT CIRCUITS USING METAL OVERLAYS IN STANDARD CELL LIBRARY

(71) Applicant: QUALCOMM Incorporated, San Diego, CA (US)

(72) Inventors: Praveen Kumar KANDUKURI, Bangalore (IN); Pavan Vithal TORVI, Bangalore (IN); Raashid Moin SHAIKH, Bangalore (IN)

(21) Appl. No.: 16/525,226

(22) Filed: Jul. 29, 2019

Related U.S. Application Data
(60) Provisional application No. 62/767,396, filed on Nov. 14, 2018.

(51) Int. Cl. H01L 23/528; H01L 23/522; G06F 17/50; H01L 27/02

(52) U.S. Cl. CPC H01L 23/528; H01L 23/5226; G06F 17/5081; H01L 27/0207; G06F 17/5077

(57) ABSTRACT

A method of generating a layout of a circuit, including placing a set of base cells on a design floorplan; placing a set of metal overlays over the set of base cells, respectively; and routing a set of interconnects between the set of metal overlays. An integrated circuit formed using this method includes a set of base cells formed on and above a substrate; a set of metal overlays formed directly over the set of base cells, respectively; and a set of interconnects electrically connecting at least one or more metal overlays together.

### CROSS-REFERENCE TO RELATED APPLICATION

This application claims the benefit of the filing date of U.S. Provisional Application, Ser. No. 62/767,396, filed on Nov. 14, 2018, which is incorporated herein by reference.

### FIELD

Aspects of the present disclosure relate generally to circuit layout techniques, and in particular, to a system and method of laying out circuits using metal overlays in standard cell library.

### DESCRIPTION OF RELATED ART

Conventional layout techniques typically involve placing a set of base cells and routing connections between the base cells using a place and route tool. However, often using these techniques, substantial variation in the lengths of data paths between base cells may exist. As a result, design closure may be difficult to be achieved for a design that requires a set of signals to arrive at the same time or within a short time interval at the input of the next stage.

Other conventional layout technique is to create a new base cell to include higher level metallization. However, this generally results in the number of base cells in a standard cell library to grow substantially. Further, the modified base cell will need to be characterized for timing and should also meet design rule checks (DRC). Moreover, the additional metallization layers of the modified base cells may only be applicable to a particular design, and may not be suitable for general or widespread applicability. As a result, the standard cell library will have base cells with limited applicability, while occupying substantial storage space in such standard cell library.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

Another aspect of the disclosure relates to an integrated circuit, including: a set of base cells formed on and above a substrate, wherein each base cell includes a set of semiconductor substrate features and a first set of one or more metallization layers electrically coupled to the set of semiconductor substrate features; a set of metal overlays for directly over the set of base cells, respectively, wherein each metal overlay comprises a second set of one or more metallization layers situated above and electrically coupled to the first set of one or more metallization layers; and a set of interconnects electrically connecting at least one or more metal overlays.

An aspect of the disclosure relates to a method of generating a layout of a circuit, including: placing a set of base cells on a design floorplan; placing a set of metal overlays over the set of base cells, respectively; and routing a set of interconnects between the set of metal overlays.

Another aspect of the disclosure relates to a computer system for generating a layout of a circuit, including a user interface; and a processor configured to place a set of base cells on a design floorplan in response to instruction received from the user interface; place a set of metal overlays over the set of base cells, respectively, floorplan in response to instruction received from the user interface; and route a set of interconnects between the set of metal overlays floorplan in response to instructions received from the user interface.

Another aspect of the disclosure relates to an integrated circuit including a set of base cells formed on and above a substrate, wherein each base cell comprises semiconductor substrate features and a first set of one or more metallization layers electrically coupled to the semiconductor substrate features; first means for electrically connecting to the semiconductor substrate features of the set of base cells, said first means situated directly over the set of base cells, respectively; and second means for electrically connecting two or more first means together, respectively.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIG. 1 illustrates a block diagram of an exemplary system for generating a circuit layout in accordance with an aspect of the disclosure.

FIG. 2 illustrates a top view of an exemplary metal overlay in accordance with another aspect of the disclosure.

FIG. 3 illustrates a top view of an exemplary base cell in accordance with another aspect of the disclosure.

FIG. 4 illustrates a flow diagram of an exemplary method of generating a circuit layout in accordance with another aspect of the disclosure.

FIG. 5 illustrates a block diagram of an exemplary memory circuit in accordance with another aspect of the disclosure.

FIG. 6 illustrates a flow diagram of an exemplary method of generating a layout for data paths of the memory circuit of FIG. 5 in accordance with another aspect of the disclosure.

FIG. 7 illustrates a top view of an exemplary layout for a memory circuit in accordance with another aspect of the disclosure.

FIG. 8 illustrates a top view of another exemplary layout for a memory circuit in accordance with another aspect of the disclosure.

FIG. 9 illustrates a top diagram of an exemplary metal overlay in accordance with another aspect of the disclosure.

FIG. 10 illustrates a top diagram of another exemplary metal overlay in accordance with another aspect of the disclosure.

FIG. 11 illustrates a diagram of variation of lengths of data paths laid out using metal overlays as compared to conventional layout method in accordance with another aspect of the disclosure.

FIG. 12 illustrates a diagram of variation in the number of vias laid out using metal overlays as compared to conventional layout method in accordance with another aspect of the disclosure.

FIG. 13 illustrates a diagram of variation in delay between repeaters laid out using metal overlays as compared to conventional layout method in accordance with another aspect of the disclosure.

FIG. 14 illustrates a table comparing characteristics of a circuit laid out using metal overlays as compared to conventional layout method in accordance with another aspect of the disclosure.

FIG. 15 illustrates a side view of an exemplary integrated circuit in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Device geometries have shrunk significantly in the advanced technology process nodes.

While feature size shrink has helped increase transistor density in integrated circuits (ICs), it has also made design closure significantly complex. A small variation in the device dimension or any other parameter during manufacturing can manifest as significant variation in transistor characteristics, which can impact IC functionality and reduce yield.

It is desirable that yield is high to make IC design and manufacturing commercially viable in these advanced technology nodes. Along with the variability, some of the transistor effects that have become prominent at lower technology nodes should be modeled as accurately as possible to improve the yield.

Several solutions have been proposed at standard cell library level and at design level to get a functionally working silicon with good yield. Some of these are: (a) LVF (Liberty Variance Format), CCS (Composite Current Source), etc., to comprehend variability and complex transistor behavior at standard cell level; and (b) timing closure at multiple signoff corners at design level. It should be noted that all proposed solutions to improve yield in advanced technologies result in higher cell library characterization effort and storage space, which, in turn, has increased library development, qualification and release effort.

For a layout to be manufacturable, it should meet certain design rules that are set by a foundry. In the advanced technology nodes, design rule complexity has increased considerably and has made layout development for a new cell a very high effort activity. Thus, having larger number of standard cells in the library will not only increase the characterization cost, but also the layout development cost.

Supporting a standard cell library with large number of cells for any PDK (Process Development Kit) updates, such as spice models or DRCs, will also incur a significant cost. Therefore, it is desirable to have a standard cell library with a limited number of cells.

Typically, custom cells with signal pins in specific metal layers and of specific shapes are developed for data path logic to ease floorplan, logic placement and design closure effort. However, due to the reasons explained earlier it is prohibitively expensive to develop and support additional cells in the advanced technology node libraries. Thus, a technique that can avoid the overhead of developing additional cells for custom requirement, but can provide the same flexibility of a custom developed cell will be useful for design community in general and for physical designers in particular. In this disclosure, metal overlays are included in the standard cell library to provide such flexibility.

Below, there is a discussion of metal overlay details and the methodology to use them in the design. This is followed by a discussion on the advantages and relevance of including metal overlay in standard cell library.

Metal overlay, as the name suggests, includes only one or more metal layers and optionally one or more vias, but does not include base layers. This is because the moment a cell has base layers, it requires characterization. Further, all lower base layers have stringent DRC requirements. Although metal overlays also need to meet DRC requirements, they are not as stringent as for the lower base layers. Thus, metal overlay avoids characterization and stringent DRC.

In contrast, a base cell includes all layers of a semiconductor substrate, and the first, second, and rarely, the third metallization layers, typically referred to as M1, M2, and

M3, respectively. Thus, a base cell may be defined as the semiconductor substrate features (e.g., drain, source, gate, channel) and a set of one or more metallization layers electrically coupled to the substrate features. A base cell may be any circuit element, such as an inverter, buffer, or other circuit.

Whereas, a metal overlay is defined as a set of one or more metallization layers (e.g., M4-M8) directly above the base cell, and specifically, above the one or more metallization layers (e.g., M1-M3) of the base cell. A metal overlay makes electrical contacts to the substrate features of the base cell, and specifically, to the one or more metallization layers of the base cell by way of one or more vias. Thus, in this regard, a metal overlay effectively promotes a signal pin of a base cell to a higher metallization layer to improve electrical routing between base cells. In other words, using metal overlays, electrical routing between base cells (e.g., from one inverter to another inverter) may be from a metal overlay associated with one base cell to the metal overlay associated with another base cell.

A metal overlay may be created in a custom layout tool and is used in the place and route tool. A metal overlay should meet the following requirements: 1) Metal overlay created will have only metal layers and optional via connections, and will not include any base layers; and 2) Typically, metal overlay will be used along with another standard cell (e.g., a base cell). Metal overlay should be DRC (Design Rule Check) clean, when placed over the base cell and should not result in DRC violations even with the abutting cells.

Some of the recommended requirements for metal overlays are: 1) If the metal overlay dimensions substantially match base cell dimensions or is substantially an integer multiple of base cell dimensions, then it will be simple to script the custom placement of the overlay cell. While this requirement is not absolutely necessary, having this will simplify custom placement scripting; and 2) Overlay should not make base cell pin-access difficult.

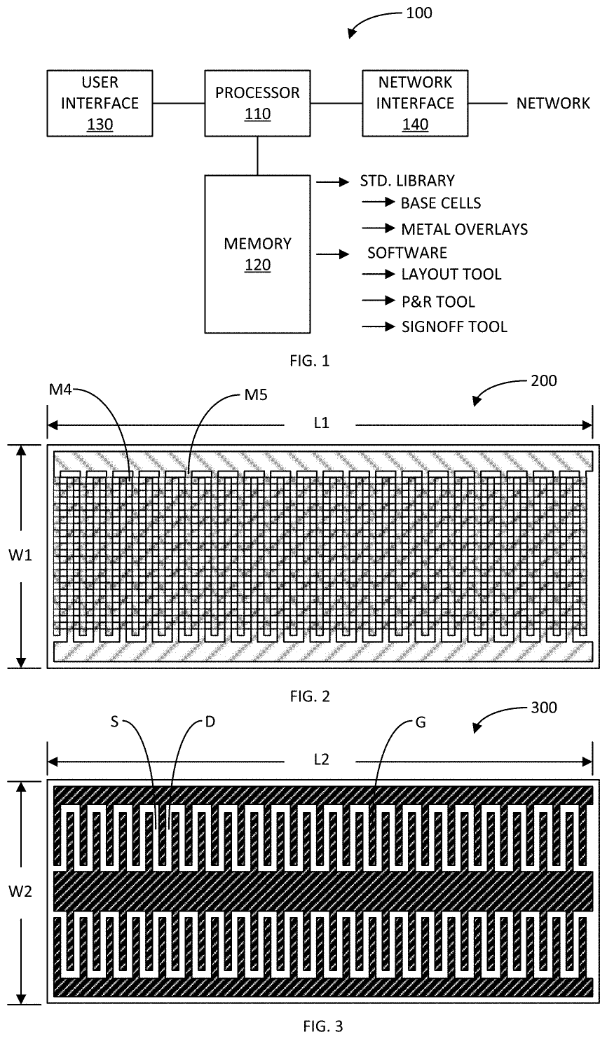

FIG. 1 illustrates a block diagram of an exemplary system 100 for generating a circuit layout in accordance with an aspect of the disclosure. The system 100 may be a computer-based system, including a processor 110 (e.g., a microprocessor), a memory device 120 (e.g., volatile memory (random access memory (RAM)), non-volatile memory (read only memory (ROM), magnetic hard disk, solid state disk, optical disc, etc., or any combination thereof), a user interface 130 (e.g., a keyboard, pointing device (e.g., mouse), microphone, display, touchscreen display, speakers, etc.), and a network interface 140 (e.g., WiFi adapter, Ethernet, Local Area Network (LAN), Bluetooth, etc.).

As discussed further herein, the processor 110 may perform all aspects of the circuit layout techniques described herein, including metal overlay generation, base cell generation, base cell placement, metal overlay placement over base cell, routing, parasitic analysis in conjunction with routing, flattening overlays, and design closure analysis. The processor 110 may perform the above operations through the use of various software modules stored in the memory device 120, such as a layout tool, place and route tool, and a signoff tool. The memory device 120 may also store a standard cell library, including a set of already-defined base cells and a set of already-defined metal overlays.

Alternatively, the software tool and/or the standard cell library or at least elements thereof may be stored in a remote storage device connected to a network. In this regard, the processor 110 may access the software tool and/or elements of the standard cell library via the network interface 140, and may also cause the storage of the same in the memory device 120.

The user interface 130 allows a user to provide information and control to the processor 130 via, for example, a graphics user interface (GUI), and receive information from the processor 130 also via the GUI. In this regard, a user is able to direct the circuit layout techniques described herein.

FIG. 2 shows an example of a metal overlay 200 in accordance with another aspect of the disclosure. This cell 200 includes only few top metals layers (e.g., M4-M8) that are not present in the base cell (e.g., M1-M3). For instance, in this example, the metal overlay includes horizontal metal layer M4 and vertical metal layer M5. Although not shown in FIG. 2, the metal overlay 200 may include one or more vias for electrically connecting the metal layers M4 and M5 to pins of a base cell over which the metal overlay is disposed.

Metal overlay will have the LEF (Library Exchange Format) CLASS attribute set to COVER. The attribute COVER indicates to the place and route tool that the metal overlay does not have any base layers. In this example, the metal overlay 200 has a dimension with a width W1 and a length L1. As discussed above, for ease of custom placement scripting, it is desirable that the dimension of the metal overlay 200 substantially match or is substantially an integer multiple of the dimension of the base cell upon which the metal overlay directly overlies.

FIG. 3 is an example of a base cell 300 on top of which the metal overlay 200 can be used. A base cell may be defined as the semiconductor substrate features (e.g., drain (D), source (S), gate (G), channel) and a set of one or more of the lowest metallization layers (e.g., M1-M3) electrically coupled directly to the semiconductor substrate features, all of which are configured to implement the operation of the base cell.

As illustrated, the base cell 300 has a dimension with a width W2 and a length L2.

Thus, as discussed above, for ease of custom placement scripting, the width W1 of the metal overlay 200 should be J times the width W2 of the base cell 300, where J is an integer of one or more; and the length L1 of the metal overlay should be K times the length L2 of the base cell 300, where K is an integer of one or more.

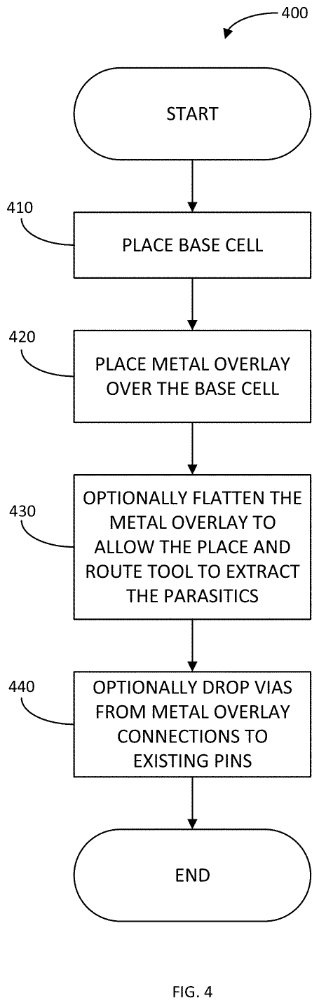

FIG. 4 illustrates a flow diagram of an exemplary method 400 of generating a circuit layout in accordance with another aspect of the disclosure. Each operation (marked by numbers in the flow chart) is explained below:

According to the method 400, the processor 110 performs a placement of a set of base cells in a design floorplan through the control of the place and route tool and/or through a custom placement script stored in the memory device 120 or at a remote computer on a network (block 410). Base cell placement methodology is driven by the design requirements and use scenarios.

Further, according to the method 400, the processor 110 identifies a subset of the set of base cells in the design over which a set of metal overlays are to be placed to achieve the set objective, and place the set of metal overlay over the subset of base cells, respectively (block 420). Typically, the placement of the set of metal overlays over the subset of base cells is done through custom scripts. Each of the metal overlays may have been created by a layout tool. The placement of a metal overlay over a base cell should not violate DRC. Therefore, metal overlays should be DRC clean. Additionally, the placement of a metal overlay over a base cell should not make access to the pins of a base cell difficult.

Further, according to the method 400, if the metal overlay parasitic values (e.g., resistance and/or capacitance) are significant and influence place and route optimization, then the processor 110 should flatten the metal overlay during place and route optimization (block 430). Flattening the metal overlay will let place and route tool treat overlay metal segments as any other design routes and consider those metal shapes for extraction. However, if the parasitics are insignificant (and if the designer feels that place and route tool will not be influenced by this parasitics), then the metal overlay can be left hierarchical. The parasitics due to the metal overlay will be extracted during signoff checks and the timing impact will be seen then. It should be noted that by maintaining the cell hierarchy, the number of nets at design level will reduce, which in turn will reduce the number of nets for which parasitics have to be extracted. This can speed-up place and route runtime.

Further, according to the method 400, if the metal overlay does not connect to the existing standard base cell metallization or pins through vias, a user (e.g., the designer), using the user interface 130, instructs the processor 110 to drop one or more vias and connect the metal overlay to the pins or metallization layer of the corresponding base cell (block 440).

Some of the applications of metal overlays are as follows:

1) Metal overlays effectively promote the pins of a base cell to a higher or a different metal layer to help custom routing. In this regard, the routing of interconnects may be made from a first metal overlay associated with a first base cell to a second metal overlay associated with a second base cell. Alternatively, the routing of interconnects may be made from a first base cell to a metal overlay associated with a second base cell, or vice-versa.

2) Metal overlays effectively allow the shape of the pins of a base cell to change to provide better access points and/or improve performance. For example, metal overlays may be configured to effectively take pins of a base cell all the way up to the boundary of an IC. In this regard, no additional routing is required.

3) Metal overlays may also improve power/ground connections to base cells. For example, the metal overlays can be widened to improve power/ground connection without recharacterizing or redoing the standard base cell library.

4) Metal overlay's can be used as metal fill/via on top of critical cells. This will not only prevent other signal routes from using the routing tracks over the critical cells, which can cause undesirable coupling, but also help in meeting the metal density requirement for manufacturing.

The above layout method flow using metal overlays was used in a memory interface block (e.g., dual data rate (DDR) memory interface) for doing custom routing, whose details are discussed below. In this endeavor, metal overlays were used to promote the repeater (e.g., buffer or inverter) pins to a higher metal layer to provide an easy access for custom routing. In the absence of metal overlay-based flow, a new cell would have to be developed to meet the design requirements. It should be noted that the new cell would have supported custom routes only in a specific horizontal layer, and for vertical custom routes yet another unique cell with pins in a different layer would have been necessary. Metal overlay-based flow ensured that with only one base cell and customized overlays, we were able to meet design requirements. Using the metal overlay flow, the memory interface block was able to achieve a very good skew matching across bus bits and the routing was DRC clean by construct.

The advantages of metal overlay flow are: 1) A new cell development is not necessary to meet design specific requirements. As previously described, creating and supporting a cell in advanced technology node is expensive. Hence any technique that can prevent a new cell addition to standard cell library is useful. 2) Metal overlay development time is significantly shorter than a custom cell development cycle time. Thus, design team can be provided with a solution sooner than if it was a custom cell solution. 3) Metal overlays do not require liberty timing models; hence, characterization is not required. Thus, several overheads such as compute and storage can be eliminated. 4) Metal overlays will be DRC clean correct-by-construct, which helps in reducing design convergence cycle time. 5) Timing accuracy is not lost at implementation place and route stage or at signoff checks stage. Place and route tool can be made to comprehend the parasitics impact during optimization by flattening the metal overlay, and if not flattened then, for signoff parasitic extraction, overlay cell LEF details should be included.

As previously explained, creating a new custom cell is expensive in advanced technology nodes. Also, for future nodes, variability will continue to increase and the transistor effects that were not impacting yield will continue to worsen, which would lead to modeling newer effects in characterization and complex layout rules. Hence, techniques that can help in keeping the base library size minimal will help.

With the increasing DRC complexity for future technology nodes, custom routing through custom routing scripts will get more complicated. Hence a solution that can avoid custom routing through scripting will aid in shortening the design convergence cycle time.

With the increasing DRAM performance and higher process variability, achieving a minimal timing skew across different data bits across several process corners is challenging. This disclosure proposes a methodology to route skew critical nets and achieve good structural matching across the bits of data bus and the strobe. The proposed methodology reduced the route length variation range, and helped in faster DDR PHY timing closure across different corners.

DDR PHY is a critical IP for System on Chips (SoCs) in general and mobile SoCs in particular. External Dynamic Random Access Memory (DRAM) interacts with the memory controller through DDR PHY macro. Data transfer rates have continued to increase with every generation of DRAM. Low power DDR4 (LPDDR4) is the latest generation DRAM in commercial production and can support data transfer rates up to 4266 Mbps per pin. This data transfer rate necessitates DDR PHY internal clocks to run at high GHz frequencies. As DRAMs have source synchronous interface, data and strobe (or clock) should be closely matched at these high frequencies.

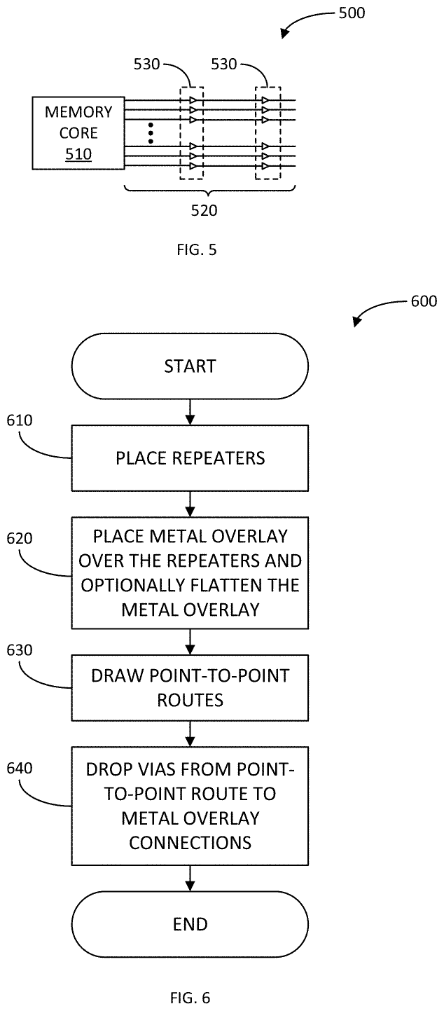

FIG. 5 illustrates a block diagram of an exemplary memory circuit 500 in accordance with another aspect of the disclosure. In this example, the memory circuit 500 is implemented as a DDR PHY, although it may be implemented differently. The memory circuit 500 includes a memory core 510 (e.g., a DRAM memory core) and an interface 520. The interface 520 may include a set of parallel conductive lines for routing data, clock, and other signals to and from the memory core 510. The interface 520 further includes one or more sets of repeaters 530 (e.g., buffers or inverters) interposed between various sections of the parallel conductive lines. Each of one or more of the sets of repeaters 530 are examples of a base cell. The one or more sets of repeaters 530 are shown buffering signals in one direction for ease of illustration, but may be configured for bidirectional signal buffering.

FIG. 6 illustrates a flow diagram of an exemplary method 600 of generating a layout for data paths of the memory circuit 500 in accordance with another aspect of the disclosure. This method 600 is basically the same as the general layout method 400 described with reference to FIG. 4, but specifically tailored for the memory circuit 500. The method 600 captures the key points of the proposed methodology. This methodology 600 has four steps: 1) Place the repeaters (specific example of a base cell): Repeaters are placed at regular intervals along the route (block 610). 2) Place metal overlays over the repeaters and optionally flatten the metal overlays (block 620). 3) Draw point-to-point routes between the metal overlays through script (block 630). 4) Drop vias from the routes to the pins of the repeaters (block 640).

In the proposed solution, metal overlay is created in a layout tool and is used in a place and route tool. The overlay created in the layout tool will have only metal layers and via connections and should meet the following requirements: 1) Metal overlay should match standard cell boundary. 2) Highest layer should provide easy access to routes done through script. 3) Should not have any DRC violations.

The LEF generated from a layout tool had to be modified to be used in a place and route tool. The metal overlay LEF was instantiated over the standard base cell such that it matched the orientation of the cell and then it was flattened using the tool native capabilities.

The advantages of this approach are as follows: 1) This is simple and provides a faster convergence—lesser noise/crosstalk, and fewer or no DRCs. 2) This approach is scalable—large number of nets were routed using this technique. 3) All routes are very well matched and has minimal skew across all the bits. 4) Routing tracks benefits: Since the place and route tool is not allowed to do the routing, off grid routing can be implemented. This provides the flexibility to have non-integer multiple of minimum-spacing distance between routes, and non-integer multiple of width of routes. This further helps pack more routes in a given area. 5) No new base cells with higher layer pin access had to be created—this avoided additional cell characterization and unnecessary library data bloat.

In the memory circuit 500, about 5000 nets were routed using the metal overlay mechanism. Since skew requirements and DRCs were correct by construct, we could achieve a quick timing and process variation (PV) convergence. Correct pre-routes also ensured that these nets were crosstalk and noise free and no fixes were necessary during the final closure.

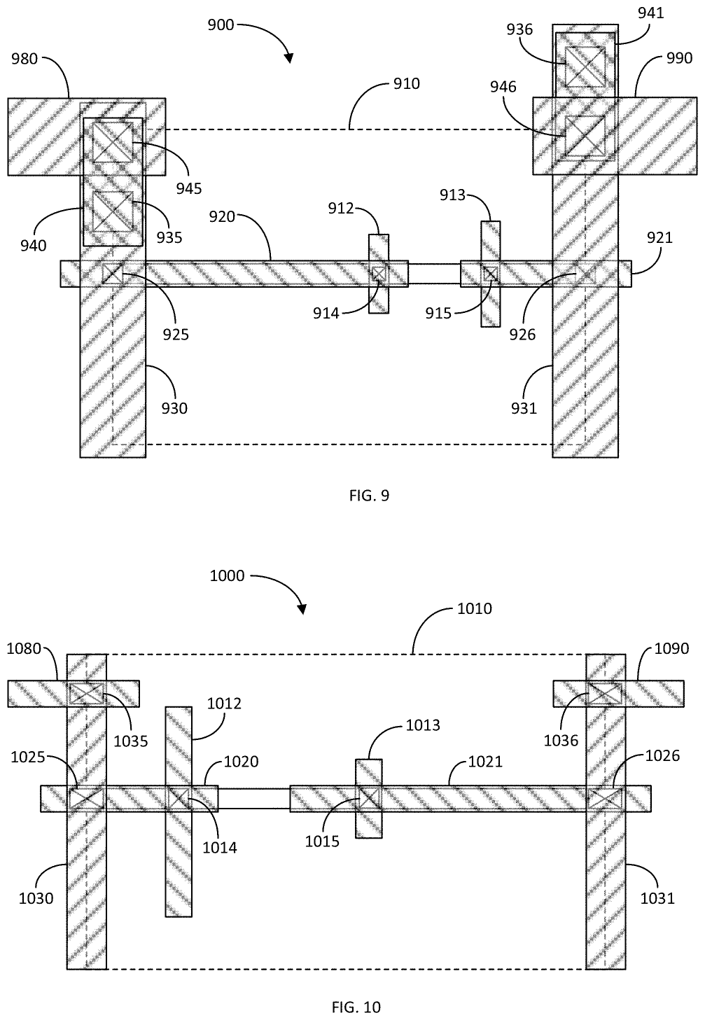

As discussed in more detail below, metal overlay LEFs created for the memory circuit 500 are shown in FIG. 9 and FIG. 10. These overlays match dimensions of the underlying base cell, and were created in a layout tool. It can be noted that by placing these metal overlays above LEF, the pins of the base cells will be promoted to a higher layer.

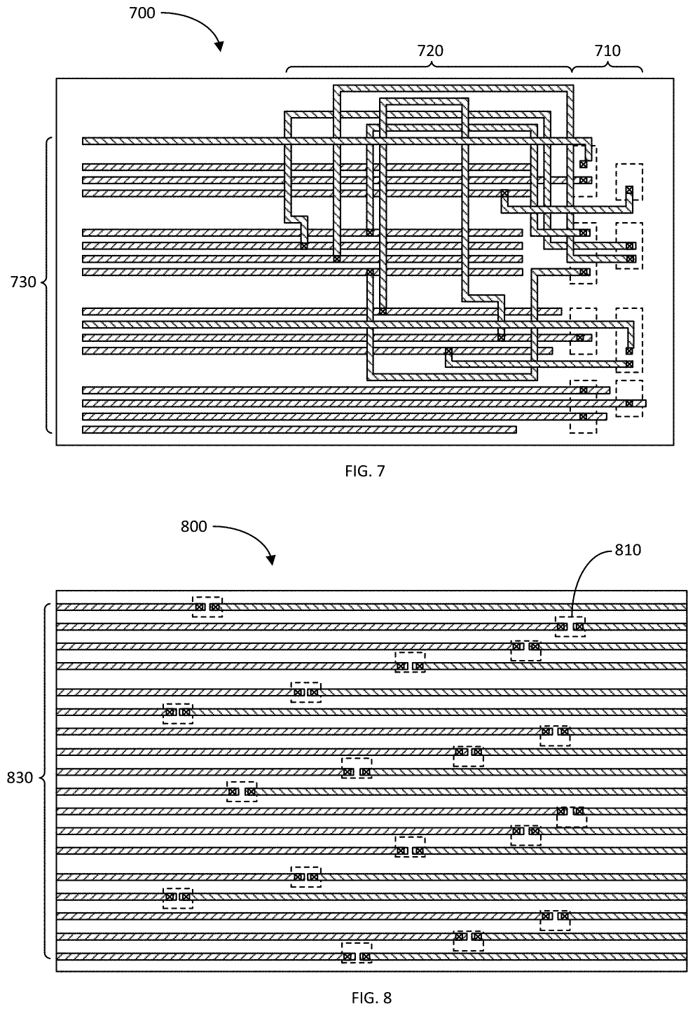

FIG. 7 shows the default place and route router-based routing of the critical nets 700 and FIG. 8 shows the routing of the nets 800 with metal overlay mechanism. The critical nets 700 includes a set of base cells 710, a set of routing lines 720 generated by a place and route tool, and a set of horizontal routing lines 730. As illustrated, the routes 720 generated by place and route tool are significantly varied and uneven in connecting the base cells 710 to the horizontal routing lines 730. The varied and uneven routes generate significant skew variation in the routing from the base cells 710 to a target destination.

The critical nets 800 of FIG. 8 includes a set of metal overlays 810 and a set of horizontal routing lines 830. It can be clearly seen that the routes done through metal overlay mechanism are very well matched in terms of distribution, lengths, and skew. Using metal overlays, a higher number of routes were packed in the same space, and included off-grid routing.

FIG. 9 illustrates a top view of an exemplary layout 900 including a metal overlay over a base cell 910 in accordance with another aspect of the disclosure. In this example, the base cell 900 includes at least one metallization layer 912 (e.g., M3), which, in turn, includes an input pin for the cell. The metal overlay includes a lower metallization layer 920 (e.g., M4) including a via 914 making electrical contact to the input pin of the base cell 910. The metal overlay further includes an intermediate metallization layer 930 (e.g., M5) electrically connected to the lower metallization layer 920 by way of a via 925. Additionally, the metal overlay includes a higher metallization layer 940 (e.g., M6) electrically connected to the intermediate metallization layer 930 by way of a via 935. The metal overlay includes a via 945 electrically connected to the higher metallization layer 935. The via 945 serves as a pin for the metal overlay, and may be electrically connected to a routing line 980.

Thus, the metal overlay promotes the input pin of the base cell 910 from being situated at metallization layer 912 (e.g., M3) to the metallization layer 940 (e.g., M6). Further, as illustrated, the metal overlay has a pin 945 that is much greater in size than the pin 914 of the base cell 910. This feature, for example, may be used to improve providing power and ground to the base cell 910 with less resistance due to the larger pin 945 of the metal overlay.

As illustrated, the metal overlay may also be configured to promote an output pin of the base cell 910 to a higher metallization layer. For example, the base cell 910 further includes an output pin 915 at metallization layer 913 (e.g., M3). The metal overlay includes a lower metallization layer 921 (e.g., M4) including a via 915 making electrical contact to the output pin of the base cell 910. The metal overlay further includes an intermediate metallization layer 931 (e.g., M5) electrically connected to the lower metallization layer 921 by way of a via 926. Additionally, the metal overlay includes a higher metallization layer 941 (e.g., M6) electrically connected to the intermediate metallization layer 931 by way of a via 936. The metal overlay includes a via 946 electrically connected to the higher metallization layer 941. The via 946 serves as a pin for the metal overlay, and may be electrically connected to a routing line 990.

Similarly, the metal overlay promotes the output pin of the base cell 910 from being situated at metallization layer 913 (e.g., M3) to the metallization layer 941 (e.g., M6). Further, as illustrated, the metal overlay has a pin 946 that is much greater in size as the pin 915 of the base cell 910. This feature, for example, may be used to improve providing power and ground to the base cell 910 with less resistance due to the larger pin 946 of the metal overlay. Also note that the metal overlay is substantially the same size as the base cell 910 (e.g., has substantially the same width and length) and is oriented in substantially the same manner as the base cell 910.

FIG. 10 illustrates a top view of another exemplary layout 1000 including a metal overlay over a base cell 1010 in accordance with another aspect of the disclosure. Similar to metal overlay of FIG. 9, the metal overlay of layout 1000 promotes an input pin of the base cell 1010 from a base metallization layer 1012 (e.g., M2) by way of a via 1014, a lower metallization layer 1020 (e.g., M3), another via 1025, an intermediate metallization layer 1030 (e.g., M4), and another via 1035 serving as the input pin of the metal overlay. The input pin 1035 is electrically connected to a routing line 1080.

Similarly, the metal overlay of layout 1000 also promotes an output pin of the base cell 1010 from a base metallization layer 1013 (e.g., M2) by way of a via 1015, a lower metallization layer 1021 (e.g., M3), another via 1026, an intermediate metallization layer 1031 (e.g., M4), and another via 1036 serving as the output pin of the metal overlay. The output pin 1036 is electrically connected to a routing line 1090.

As illustrated, the metal overlay has pins 1035 and 1036 that is much greater in size and rectangular-in-shape as compared to the square-shape pins 1014 and 1015 of the base cell 1010. Again, this feature, for example, may be used to improve electrical connection to the base cell 1010 with less resistance due to the larger pins 1035 and 1036 of the metal overlay. Also note that the metal overlay is substantially the same size as the base cell 1010 (e.g., has substantially the same width and length) and is oriented in substantially the same manner as the base cell 1010.

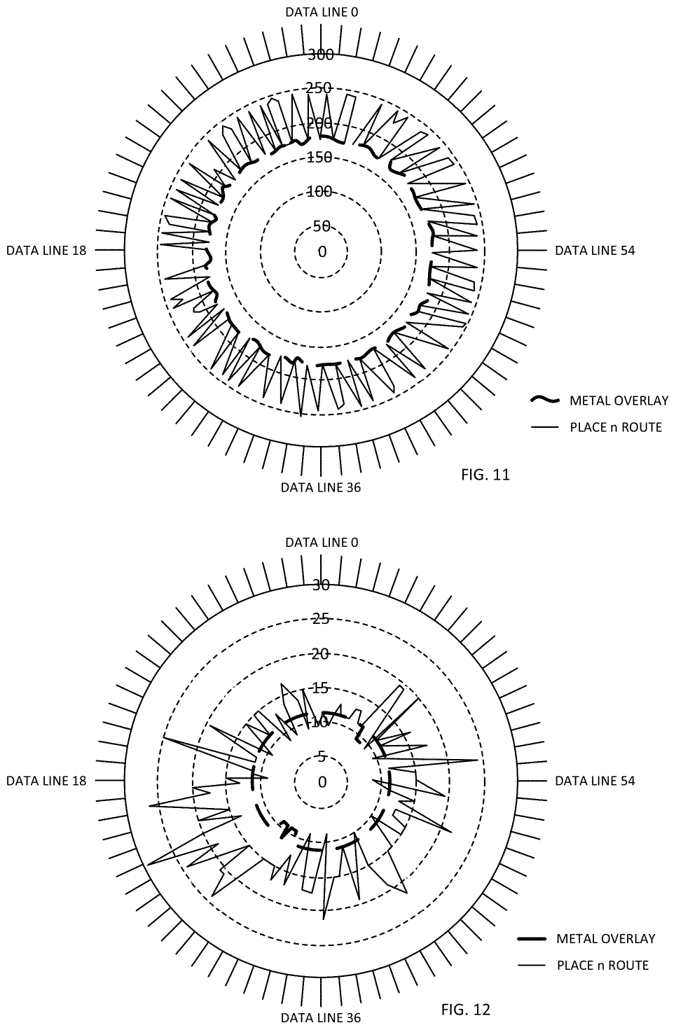

FIG. 11 illustrates a diagram of variation of lengths of data paths laid out using metal overlays as compared to conventional layout method in accordance with another aspect of the disclosure. The diagram is configured similar to a bullseye with an inner circle indicating lengths 50 nanometers (nm) or less, a next larger ring-shaped region indicating lengths between 50 nm to 100 nm, a next larger ring-shaped region indicating lengths between 100 nm to 150 nm, and so on, to the largest ring-shaped region indicating lengths between 250 nm to 300 nm. The radial lines around the 300 nm-length circle identifies the data lines or paths, with data line 0 at the top, data line 18 on the left, data line 36 at the bottom, and data line 54 on the right.

The lengths of all the nets or data lines done through overlay mechanism (thicker line) and with the default place and route tool (thinner line) are plotted in FIG. 11. As illustrated, the lengths of the data lines generated using the metal overlay technique are substantially constant at around 180 nm. Whereas, the lengths of the data lines generated using the place and route technique vary significantly between 180 nm and 250 nm. It can be clearly observed that the metal overlay technique provides more uniform data line lengths as compared to that of the default place and route-based routing.

FIG. 12 illustrates a diagram of variation of the number of vias laid out using metal overlays as compared to conventional layout method in accordance with another aspect of the disclosure. The diagram is similar to the diagram of FIG. 11 including a bullseye with an inner circle indicating vias of 5 or less, a next larger ring-shaped region indicating vias between 5 to 10, a next larger ring-shaped region indicating vias between 10 to 15, and so on, to the largest ring-shaped region indicating vias between 25 to 30. The radial lines around the 300 nm-length circle identifies the data lines or paths, with data line 0 at the top, data line 18 on the left, data line 36 at the bottom, and data line 54 on the right.

Additionally, the number of vias in all of the nets done through metal overlay mechanism (thicker line) and with the default place and route tool (thinner line) are plotted in FIG. 12. As illustrated, the number of vias generated using the metal overlay technique is substantially constant at around 12. Whereas, the number of vias generated using the place and route technique vary significantly between 8 and 30. It can be clearly observed that the number of vias generated using the metal overlay technique is smaller and more uniform than the number of vias generated with the default place and route-based routing.

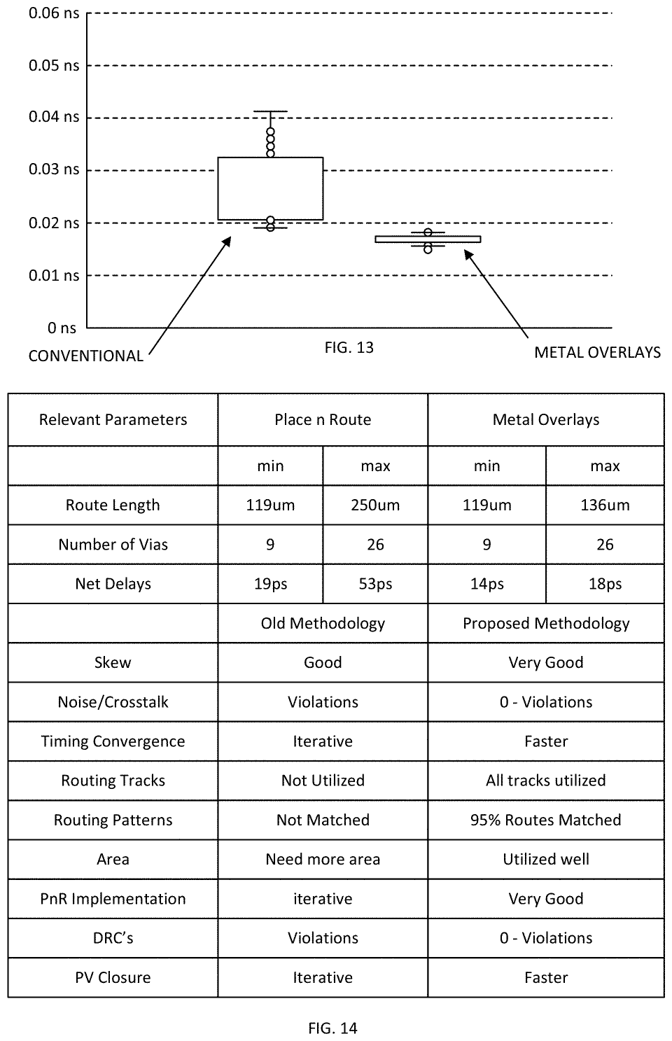

FIG. 13 illustrates a diagram of variation in delay between repeaters laid out using metal overlays as compared to conventional layout method in accordance with another aspect of the disclosure. The y- or vertical-axis represents delays ranging from zero (0) nanosecond (ns) to 0.06 ns. The left-diagram along the x- or horizontal-axis represents the delays between repeaters associated with conventional layout method. The right-diagram along the x- or horizontal-axis represents the delays between repeaters associated with metal overlay layout method.

As the diagram illustrates, the delays between repeaters associated with the conventional layout method ranges between 0.02 ns and 0.04 ns. Whereas, the delays between repeaters associated with the metal overlay layout method are substantially constant at 0.018 ns. It can be clearly observed that the delay variation using metal overlays is significantly smaller and more uniform than the default place and route-based routing.

FIG. 14 illustrates a table comparing characteristics of a circuit laid out using metal overlays as compared to conventional (place and route) layout method in accordance with another aspect of the disclosure. The benefits of default place and route tool-based routing are compared with that of custom overlay-based routing in the table. It can be clearly seen that the custom overlay-based approach is better than the other.

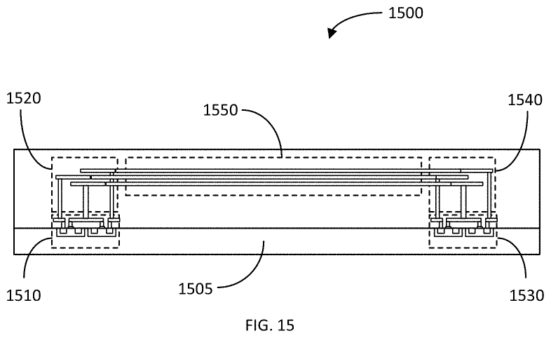

FIG. 15 illustrates a side view of an exemplary integrated circuit (IC) 1500 in accordance with another aspect of the disclosure. In this example, the IC 1500 includes a pair of base cells 1510 and 1530 (e.g., may be configured as repeaters, such as inverters or buffers), a pair of metal overlays 1520 and 1540 directly overlying the base cells 1510 and 1530, respectively, and interconnect routing 1550 electrically connecting the metal overlay 1520 to the metal overlay 1540.

As illustrated, each of the base cells 1510 and 1530 include features (e.g., drain, source, channel, gate (e.g., polysilicon)) associated with a semiconductor substrate 1505, and also one or more of the lowest metallization layers (e.g., M1) electrically connecting the semiconductor substrate features.

Each of the metal overlays 1520 and 1540 include one or more metallization layers (e.g., M4-M8) situated above the one or more metallization layers (e.g., M1) of the base cells 1510 and 1530. Each of the metal overlays 1520 and 1540 may include one or more vias for electrically connecting the one or more metallization layers of the metal overlay to the features of the corresponding base cells 1510 and 1530.

The interconnect routing 1550 includes one or more metallization layers (e.g., M4-M8) electrically connected to the one or more metallization layers of the metal overlay 1520 and to the one or more metallization layers of the metal overlay 1540.

Thus, as discussed above in detail, the layout methodology includes placing the base cells 1510 and 1530 on the design floorplan. The placing of the base cells 1510 and 1530 may be performed using a place and route tool or through a custom placement script. As discussed, the placement of the base cells 1510 and 1530 is driven by design requirements and use scenarios.

After the placement of the base cells 1510 and 1530 has been performed, the metal overlays 1520 and 1540 are placed directly over the base cells 1510 and 1530, respectively. As discussed, it is preferred that the dimensions of the metal overlays 1520 and 1540 are substantially the same or integer multiple of the base cells 1510 and 1530, respectively. In the illustrated example, the dimensions of the metal overlays 1520 and 1540 are substantially the same as the dimensions of the base cells 1510 and 1530, respectively.

If the designer feels that the parasitics of the metal overlays 1520 and 1540 may affect the place and route of the layout, then the metal overlays 1520 and 1540 may be flattened during place and route optimization so that the place and route tool may take the parasitics into account in this regard. Otherwise, if the designer feels that the parasitics of the metal overlays 1520 and 1540 are not going to significantly affect the place and route, the metal overlays 1520 and 1540 may be left hierarchical.

In this example, the metal overlays 1520 and 1540 include metallized vias electrically connecting the one or more metallization layers of the metal overlays 1520 and 1540 to the one or more metallization layers or features of the base cells 1510 and 1530, respectively. If the metal overlays 1520 and 1540 did not include such metallized vias, then such vias may be added to the layout at this time.

Once the base cells 1510 and 1530 and metal overlays 1520 and 1540 are placed, with metallized vias of the metal overlays 1520 and 1540 electrically connected to the pins of the base cells 1510 and 1530, respectively, the place and route tool generates the interconnect routing 1550 for electrically connecting the one or more metallization layers of the metal overlay 1520 to the one or more metallization layers of the metal overlay 1540.

Accordingly, through the use of metal overlays, the pins (power/ground/signal) of the base cells 1510 and 1530 are effectively promoted to higher metallization layers (e.g., M4-M8), which makes it easier for the place and route tool to route between metal overlays as compared to that of routing between base cells without metal overlays. As discussed above, there are many benefits for using metal overlays, such as less variation in the lengths of data paths, data path delays are subject to less variation, skews are more consistent, metallized via are more consistently uniformly distributed, and other benefits as discussed above and tabulated in FIG. 14.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An integrated circuit, comprising:
a set of base cells formed on and above a substrate, wherein each base cell comprises semiconductor substrate features and a first set of one or more metallization layers electrically coupled to the semiconductor substrate features;
a set of metal overlays formed directly over the set of base cells, respectively, wherein each metal overlay comprises a second set of one or more metallization layers situated directly above and electrically coupled to the first set of one or more metallization layers; and
a set of interconnects electrically connecting at least one or more metal overlays together.

2. The integrated circuit of claim 1, wherein the set of metal overlays are electrically connected to the semiconductor substrate features of the set of base cells, respectively.

3. The integrated circuit of claim 1, wherein the second set of the metallization layers are electrically coupled to pins of the corresponding base cell.

4. The integrated circuit of claim 1, wherein each of the set of metal overlays includes at least one via electrically connecting at least one of the second set of one or more metallization layers to at least one of the first set of one or more metallization layers.

5. The integrated circuit of claim 4, wherein each of the set of metal overlays includes at least another via electrically connecting at least one of the second set of metallization layer to at least one of the set of interconnects.

6. The integrated circuit of claim 5, wherein the at least another via electrically connecting the at least one of the second set of metallization layer to the at least one of the set of interconnects has a size and shape different than the at least one via electrically connecting the at least one of the second set of one or more metallization layers to the at least one of the first set of one or more metallization layers.

7. The integrated circuit of claim 1, further comprising a second set of one or more metal overlays that does not make electrical contact to another set of one or more base cells over which the second set of metal overlays are situated, respectively, wherein the second set of one or more metal overlays serves as filler metal overlays.

8. The integrated circuit of claim 1, wherein at least one of the set of metal overlays has a width and length that is substantially the same or an integer multiple of a width and length of at least one of the set of base cell over which the at least one of the set of metal overlays is situated, respectively.

9. The integrated circuit of claim 1, wherein at least one of the set of metal overlays has an orientation substantially the same as at least one of the set of base cell over which the at least one of the set of metal overlays is situated.

10. The integrated circuit of claim 1, wherein a spacing between adjacent ones of the set of interconnects is a non-integer multiple of a minimum spacing between adjacent interconnects or the width of at least one of the set of interconnects is a non-integer multiple of widths of other interconnects.

11. A method of generating a layout of a circuit, comprising:
placing a set of base cells on a design floorplan;
placing a set of metal overlays over the set of base cells, respectively; and
routing a set of interconnects between the set of metal overlays.

12. The method of claim 11, wherein the placing the set of base cells on the design floorplan is performed with an assistance of a place and route tool.

13. The method of claim 11, wherein the placing the set of base cells on the design floorplan is performed with an assistance of a custom script.

14. The method of claim 11, wherein placing the set of metal overlays comprises placing the metal overlays directly over the set of base cells, respectively.

15. The method of claim 11, wherein the set of metal overlays include via electrical connections to the set of base cells, respectively.

16. The method of claim 11, further comprising adding metallized vias holes for electrically connecting the set of metal overlays to the set of base cells, respectively.

17. The method of claim 11, wherein at least one of the metal overlays is configured as a metal fill to prevent other interconnect to be routed over the at least one of the base cell over which the at least one of the metal overlays is situated.

18. An integrated circuit, comprising:
a set of base cells formed on and above a substrate, wherein each base cell comprises semiconductor substrate features and a first set of one or more metallization layers electrically coupled to the semiconductor substrate features;
first means for electrically connecting to the semiconductor substrate features of the set of base cells, said first means situated directly over the set of base cells, respectively; and
second means for electrically connecting two or more first means together, respectively.

19. The integrated circuit of claim 18, wherein the first means are electrically connected to pins of the base cells directly over which the first means are situated, respectively.

20. The integrated circuit of claim 18, wherein the first means includes vias electrically connected to pins of the base cell directly over which the first means are situated, respectively.

21. The integrated circuit of claim 18, wherein the first means includes vias electrically connected to the second means.

22. The integrated circuit of claim 18, wherein the first means has a width and length that is substantially the same or an integer multiple of a width and length of the base cells directly over which the first means are situated, respectively.

23. The integrated circuit of claim 18, wherein first means has an orientation substantially the same as the base cells directly over which the first means are located, respectively.

24. The integrated circuit of claim 18, wherein the second means includes a set of interconnects that are spaced apart from each other by a non-integer multiple of a spacing between other adjacent interconnects.

25. The integrated circuit of claim 18, wherein the second means includes a set of interconnects each having a width being a non-integer multiple of a width of other set of one or more interconnects.
